(19) United States
(12) Patent Application Publication
(10) Pub. No.: US 2006/0250161 A1
(43) Pub. Date: Nov. 9, 2006

(54) Fast linear phase detector

(76) Inventor: Mihai Adrian Tiberiu Sanduleanu, Eindhoven (NL)

Correspondence Address: PHILIPS INTELLECTUAL PROPERTY & STANDARDS, P.O. BOX 3001, BRIARCLIFF MANOR, NY, 10510, US

(21) Appl. No.: 10/550,341

(22) PCT Filed: Mar. 22, 2004
(86) PCT No.: PCT/IB04/50313

§ 371 Date: Sep. 23, 2005

(30) Foreign Application Priority Data
Mar. 28, 2003 (EP) 03100828.7

(51) Int. Cl. G01R 29/00

(52) U.S. Cl. 327/2

(57) ABSTRACT

Linear phase detectors comprising circuits (1,2) receiving reference signals (REF) and first and second clock signals (CLK-Q, CLK-I) for generating first and second (phase) control signals (UP,DOWN) for use in multiplier circuits, demodulators and receivers, have large delays due to long path lengths and many operations between input and output (insight). They can be made faster by providing each circuit (1,2) with two parallel latches (10,11,20,21) and a multiplexer (12,22) for multiplexing latch output signals (basic idea). Said multiplexers generate (frequency control) signals to be supplied to frequency detectors, with a third circuit (3) generating at least one of said (phase) control signals (UP,DOWN). Said third circuit (3) comprises a latch (30) generating said first (phase) control signal (UP), with one of the latches (20) of the second circuit (2) generating the second (phase) control signal (DOWN. Or said third circuit (3) comprises logical circuitry (31-34) comprising four EXOR gates (31-34). A fifth EXOR gate (35) is used for balancing the third circuit (3).

The invention relates to a linear phase detector for in response to at least one reference signal and at least a first and second clock signal generating at least a first and second control signal and comprising at least a first circuit receiving said reference signal and said first clock signal and a second circuit receiving said reference signal and said second clock signal.

The invention also relates to an apparatus comprising a linear phase detector, and to a method for linearly phase detecting, and to a processor program product for linearly phase detecting.

Such a linear phase detector is for example used in an apparatus comprising for example clock multiplier circuits, phase demodulators and/or zero-IF receivers etc. Said linear phase detector controls the phase of a clock (like for example a controlled oscillator) which needs to be synchronized with the reference signal having predictable edges and for example having a 50% duty cycle. Thereto, said first control signal for example comprises an up signal or comprises an error signal, and said second control signal for example comprises a down signal or comprises a basic (non-error) signal etc.

Said apparatus for example corresponds with a mobile phone, an audio receiver, an audio/video receiver etc.

A prior art linear phase detector is known from U.S. Pat. No. 5,712,580, which discloses a linear phase detector generating an up signal via a first D-flip-flop receiving an input signal from a second D-flip-flop situated in a feedback loop and generating a down signal via a third D-flip-flop receiving an input signal from said first D-flip-flop, based upon quadrature clock signals.

The known linear phase detector is disadvantageous, inter alia, due to being slow: said feedback loop, said D-flip-flops each comprising two latches and the triple D-flip-flop construction necessary for generating said down signal make this linear phase detector unsuitable for operation at higher frequencies.

It is an object of the invention, inter alia, of providing a faster linear phase detector suitable for operation at higher frequencies.

Further objects of the invention are, inter alia, providing an apparatus, a faster method, and a faster processor program product.

The linear phase detector according to the invention for in response to at least one reference signal and at least a first and second clock signal generating at least a first and second control signal comprises at least a first circuit receiving said reference signal and said first clock signal and a second circuit receiving said reference signal and said second clock signal, wherein said first and second circuits each comprise at least two latches and at least one multiplexer for multiplexing latch output signals, with said linear phase detector comprising a third circuit for generating at least one of said control signals.

By providing the linear phase detector according to the invention with parallel latches and multiplexers for multiplexing latch output signals, each pair of parallel latches will operate substantially simultaneously, with the multiplexer multiplexing the results from these operations. As a result, the delay from inputs of said linear phase detector (inputs of said first and/or second circuits) to outputs of said linear phase detector (outputs of said first and/or second and/or third circuit) is reduced, which makes the linear phase detector faster. Due to outputs of said multiplexers generating (frequency control) signals to be supplied to for example a frequency detector, said third circuit is necessary for generating at least one of said (phase) control signals.

It should be noted that each pair of parallel latches is defined to be parallel due to operating substantially simultaneously (substantially, due to possible different path lengths, different parasitic capacitors etc.) because of both receiving at least one same input signal (a data signal or a clock signal etc.) and/or because of both latches supplying their outputs signals to the same multiplexer. So, said pair of latches receive at least one same input signal and/or supply their output signals to the same multiplexer. Said latches are, in other words, multiplexed latches.

A first embodiment of the linear phase detector according to the invention is defined by claim 2.

By introducing said third circuit in the form of a latch receiving said first and second clock signal and generating said first control signal, with one of the latches of the second circuit generating the second control signal, a fast, low complex, low cost and low power consuming linear phase detector has been constructed.

A second embodiment of the linear phase detector according to the invention is defined by claim 3.

By supplying said reference signal to at least one control input of said multiplexers and to clock inputs of said latches of said first and second circuits, with said first clock signal being supplied to at least one data input of said latches of said first circuit and with said second clock signal being supplied to at least one data input of said latches of said second circuit, said linear phase detector can be easily implemented in silicon.

A third embodiment of the linear phase detector according to the invention is defined by claim 4.

By introducing said third circuit in the form of first logical circuitry receiving the latch output signals of said first circuit for generating said first control signal and comprises second logical circuitry receiving the latch output signals of said second circuit for generating said second control signal, an even faster (compared to said first embodiment), low complex, low cost and low power consuming linear phase detector has been constructed (logical circuitry is faster—has smaller delays—than latches).

A fourth embodiment of the linear phase detector according to the invention is defined by claim 5.

By using logical circuitries comprising EXOR gates, said linear phase detector is of the lowest complexity.

A fifth embodiment of the linear phase detector according to the invention is defined by claim 6.

By introducing said fifth EXOR gate, the third circuit has been balanced, and delays present from inputs of said linear phase detector to the outputs of said third circuit will be substantially identical, which is advantageous.

A sixth embodiment of the linear phase detector according to the invention is defined by claim 7.

By supplying said reference signal to at least one control input of said multiplexers and to clock inputs of said latches, with said first clock signal being supplied to at least one data input of said latches of said first circuit and with said second clock signal being supplied to at least one data input of said latches of said second circuit, said linear phase detector can be easily implemented in silicon.

It should further be noted that prior art non-linear phase detectors exist comprising multiplexed parallel latches. However, firstly, said prior art phase detectors are non-linear phase detectors, and secondly, in said prior art non-linear phase detectors, said control signals are generated in response to data signals having unpredictable edges. The control signals in the phase detectors according to the invention are generated in response to reference signals having predictable edges (and for example 50% duty cycles). Thirdly, in said prior art phase detectors at least one control signal originates from (or is derived from) an multiplexer output signal, where the control signals in the phase detectors according to the invention are generated sooner (before the multiplexers are involved). This all results in said prior art non-linear phase detectors operating completely differently.

Embodiments of apparatus according to the invention, of the method according to the invention and of the processor program product according to the invention correspond with the embodiments of the linear phase detector according to the invention.

The invention is based upon an insight, inter alia, that, generally, delay depends upon path lengths present from input to output and upon the number of operations performed between input and output, and is based upon a basic idea, inter alia, that, in a linear phase detector, a pair of parallel latches plus multiplexer per circuit will minimize this delay (minimum path length and minimum number of operations).

The invention solves the problem, inter alia, of providing a faster linear phase detector, and is advantageous, inter alia, in that such a faster linear phase detector can operate at higher frequencies, whereby said linear phase detector can be further improved by introducing low complex, low cost and low power consuming embodiments for said third circuit

These and other aspects of the invention will be apparent from and elucidated with reference to the embodiments(s) described hereinafter.

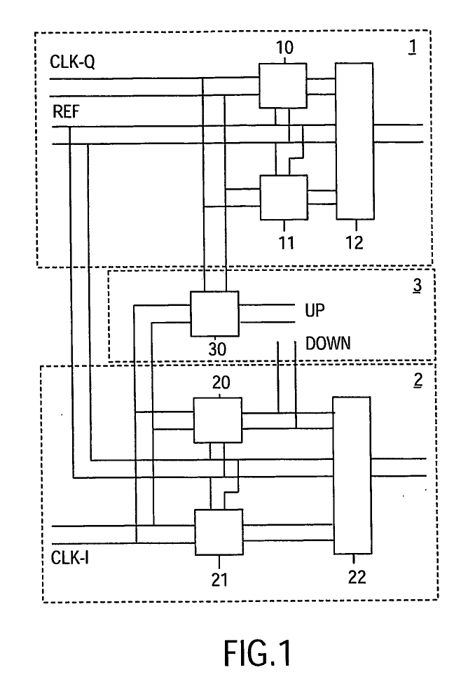

FIG. 1 illustrates in block diagram form a linear phase detector according to the invention comprising a latch for generating a control signal,

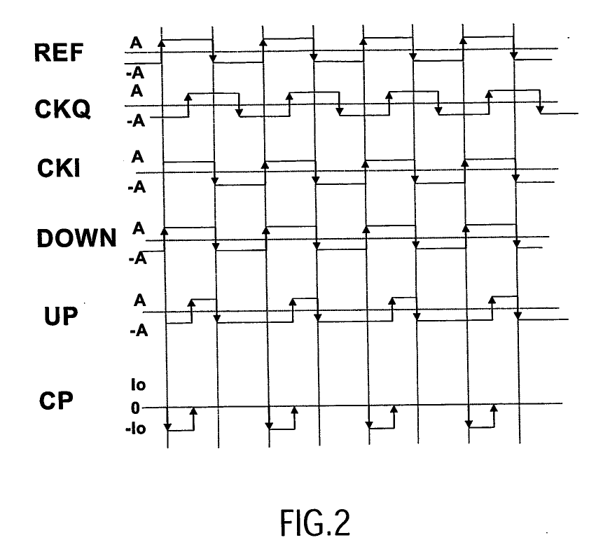

FIG. 2 illustrates in block diagram form a timing diagram for said linear phase detector shown in FIG. 1 in case of a first clock signal CLK-Q being early,

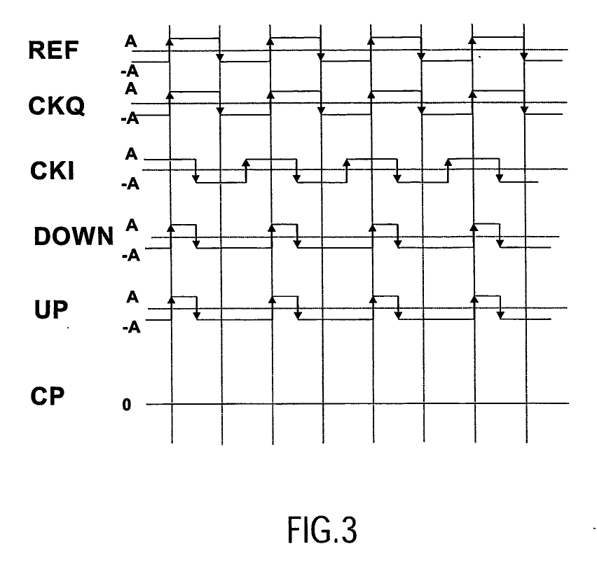

FIG. 3 illustrates in block diagram form a timing diagram for said linear phase detector shown in FIG. 1 in case of a first clock signal CLK-Q being in phase,

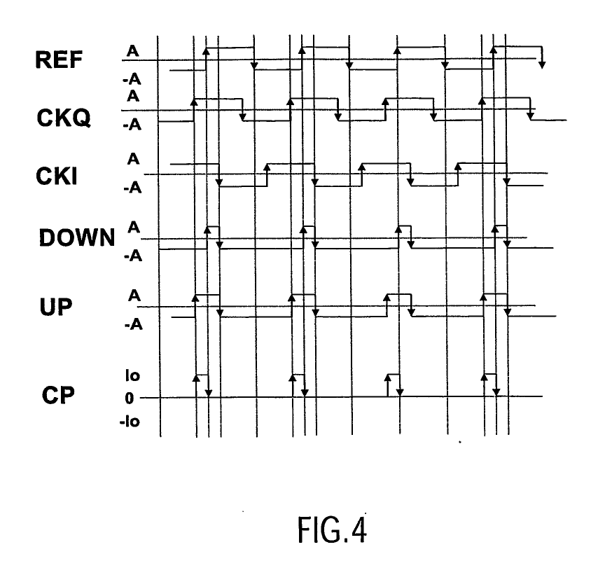

FIG. 4 illustrates in block diagram form a timing diagram for said linear phase detector shown in FIG. 1 in case of a first clock signal CLK-Q being late,

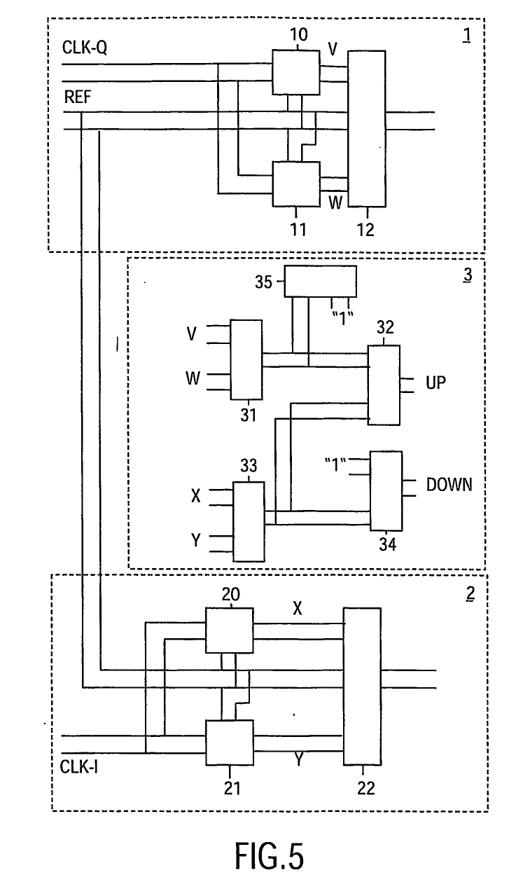

FIG. 5 illustrates in block diagram form a linear phase detector according to the invention comprising first and second logical circuitry for generating control signals,

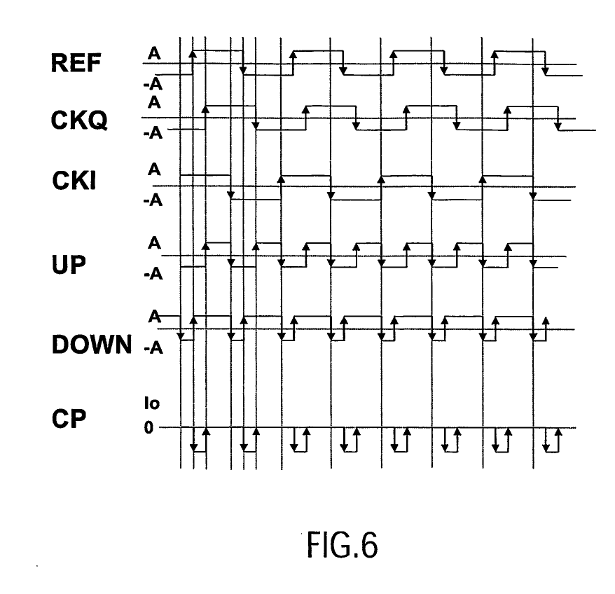

FIG. 6 illustrates in block diagram form a timing diagram for said linear phase detector shown in FIG. 5 in case of a first clock signal CLK-Q being early,

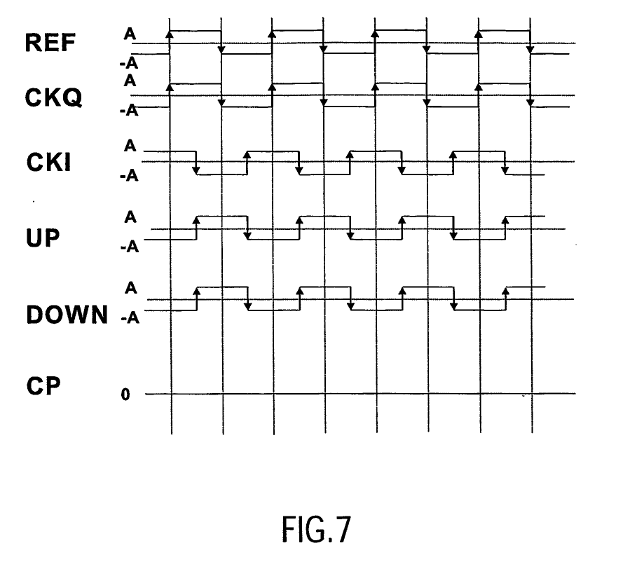

FIG. 7 illustrates in block diagram form a timing diagram for said linear phase detector shown in FIG. 5 in case of a first clock signal CLK-Q being in phase, and

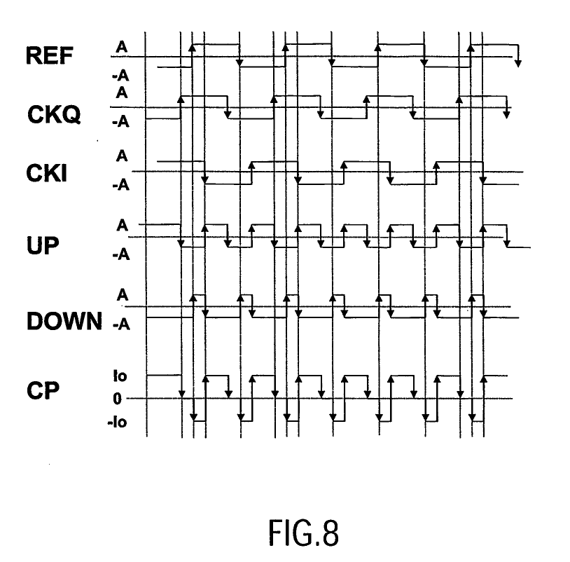

FIG. 8 illustrates in block diagram form a timing diagram for said linear phase detector shown in FIG. 5 in case of a first clock signal CLK-Q being late.

The linear phase detector according to the invention shown in FIG. 1 comprises a first circuit 1 with a latch 10 receiving at its data inputs (with the upper being the normal data input and with the lower being the inverted data input) the first clock signals CLK-Q and receiving at its respective clock inputs (with the left clock input being the normal clock input and with the right clock input being the inverted clock input) the reference signals REF. A normal output (the upper output) of latch 10 is coupled to a first normal input of a multiplexer 12, and an inverted output (the lower output) of latch 10 is coupled to a first inverted input of multiplexer 12.

Circuit 1 further comprises a latch 11 receiving at its data inputs (with the upper being the normal data input and with the lower being the inverted data input) the first clock signals CLK-Q and receiving at its respective clock inputs (with the left clock input being the normal clock input and with the right clock input being the inverted clock input) the reference signals REF, compared to latch 10, exchanged connections. A normal output (the lower output) of latch 11 is coupled to a second inverted input of multiplexer 12, and an inverted output (the higher output) of latch 11 is coupled to a second normal input of multiplexer 12.

Multiplexer 12 receives at its control inputs (with the upper being the normal control input and with the lower being the inverted control input) said reference signals REF via, compared to latch 10, non-exchanged connections, and generates at its outputs a first frequency control signal destined for a frequency detector.

The linear phase detector according to the invention shown in FIG. 1 further comprises a second circuit 2 with a latch 20 receiving at its data inputs (with the upper being the normal data input and with the lower being the inverted data input) the second clock signals CLK-I and receiving at its respective clock inputs (with the left clock input being the normal clock input and with the right clock input being the inverted clock input) the reference signals REF via, compared to latch 10, exchanged connections. A normal output (the upper output) of latch 20 is coupled to a first normal input of a multiplexer 22, and an inverted output (the lower output) of latch 20 is coupled to a first inverted input of multiplexer 22. Further, at its outputs, latch 20 generates the second (phase) control signal DOWN.

Circuit 2 further comprises a latch 21 receiving at its data inputs (with the upper being the normal data input and with the lower being the inverted data input) the second clock signals CLK-I via, compared to latch 20, exchanged connections, and receiving at its respective clock inputs (with the left clock input being the normal clock input and with the right clock input being the inverted clock input) the reference signals REF via, compared to latch 20, exchanged connections. A normal output (the lower output) of latch 21 is coupled to a second inverted input of multiplexer 22, and an inverted output (the higher output) of latch 21 is coupled to a second normal input of multiplexer 22.

Multiplexer 22 receives at its control inputs (with the upper being the normal control input and with the lower being the inverted control input) said reference signals REF via, compared to latch 20, non-exchanged connections, and generates at its outputs a second frequency control signal destined for a frequency detector.

The linear phase detector according to the invention shown in FIG. 1 further comprises a third circuit 3 comprising a latch 30 receiving at its data inputs (with the upper being the normal data input and with the lower being the inverted data input) the second clock signals CLK-I via, compared to latch 20, non-exchanged connections, and receiving at its respective clock inputs (with the left clock input being the normal clock input and with the right clock input being the inverted clock input) the first clock signals CLK-Q via, compared to latch 10, non-exchanged connections. Further, at its outputs, latch 30 generates the first (phase) control signal UP.

The timing diagrams of the linear phase detector illustrated in FIG. 1 are shown in FIGS. 2, 3 and 4 respectively in case of a first clock signal CLK-Q being early, in phase and late respectively, with REF being the reference signal, with CKQ being the first clock signal, with CKI being the second clock signal, with DOWN being the second (phase) control signal, with UP being the first (phase) control signal, and with CP being the difference between said first and second (phase) control signal.

The linear phase detector according to the invention shown in FIG. 5 comprises first circuit 1 and second circuit 2 already described for FIG. 1, and comprises third circuit 3 now comprising a first logical circuitry 31,32,35 with at least first and second EXOR gate 31 and 32, and preferably fifth EXOR gate 35, and comprising a second logical circuitry 33,34 comprising at least third and fourth EXOR gate 33 and 34.

EXOR gate 31 receives signals V and W being the output signals of latches 10 and 11. EXOR gate 33 receives signals X and Y being the output signals of latches 20 and 21. EXOR gate 32 receives the output signals from EXOR gate 31 and from EXOR gate 32 and generates said first (phase) control signal UP. EXOR gate 34 receives the output signals from EXOR gate 33 and receives a “1” signal (from a source like for example a voltage supply etc.) and generates said second (phase) control signal DOWN. EXOR gate 35 receives the outputs signals from EXOR gate 31 receives a “1” signal (from a source like for example a voltage supply etc.), just for balancing said third circuit 3: for example when looking forward from each one of the outputs of EXOR gates 31 and 33, the same impedance of two parallel inputs of two different EXOR gates can be found. This results in delays in both the UP path and the DOWN path being substantially identical, which is advantageous.

The timing diagrams of the linear phase detector illustrated in FIG. 5 are shown in FIGS. 6, 7 and 8 respectively in case of a first clock signal CLK-Q being early, in phase and late respectively, with REF being the reference signal, with CKQ being the first clock signal, with CKI being the second clock signal, with DOWN being the second (phase) control signal, with UP being the first (phase) control signal, and with CP being the difference between said first and second (phase) control signal.

The linear phase detectors shown in FIGS. 1 and 5 have double connections to fulfil the so-called balanced situation. But the invention is not limited to this balanced situation and can be used in the so-called unbalanced situation as well, with single connections.

The expression “for” in “for K” and “for L” does not exclude that other functions “for M” etc. are performed as well, simultaneously or not. The expressions “X coupled to Y” and “a coupling between X and Y” and “coupling/couples X and Y” etc. do not exclude that an element Z is in between X and Y. The expressions “T comprises Q” and “T comprising Q” etc. do not exclude that an element R is comprised/included as well.

It should be noted that the above-mentioned embodiments illustrate rather than limit the invention, and that those skilled in the art will be able to design many alternative embodiments without departing from the scope of the appended claims. In the claims, any reference signs placed between parentheses shall not be construed as limiting the claim. Use of the verb “comprise” and its conjugations does not exclude the presence of elements or steps other than those stated in a claim. The article “a” or “an” preceding an element does not exclude the presence of a plurality of such elements. The invention may be implemented by means of hardware comprising several distinct elements, and by means of a suitably programmed computer. In the device claim enumerating several means, several of these means may be embodied by one and the same item of hardware. The mere fact that certain measures are recited in mutually different dependent claims does not indicate that a combination of these measures cannot be used to advantage.

The invention is based upon an insight, inter alia, that, generally, delay depends upon path lengths present from input to output and upon the number of operations performed between input and output, and is based upon a basic idea, inter alia, that, in a linear phase detector, a pair of parallel latches plus multiplexer per circuit will minimize this delay (minimum path length and minimum number of operations).

The invention solves the problem, inter alia, of providing a faster linear phase detector, and is advantageous, inter alia, in that such a faster linear phase detector can operate at higher frequencies, whereby said linear phase detector can be further improved by introducing low complex, low cost and low power consuming embodiments for said third circuit

1. Linear phase detector for in response to at least one reference signal (REF) and at least a first (CLK-Q) and second (CLK-I) clock signal generating at least a first (UP) and second (DOWN) control signal and comprising at least a first circuit (1) receiving said reference signal (REF) and said first clock signal (CLK-Q) and a second circuit (2) receiving said reference signal (REF) and said second clock signal (CLK-I), wherein said first and second circuits (1,2) each comprise at least two latches (10,11,20,21) and at least one multiplexer (12,22) for multiplexing latch output signals, with said linear phase detector comprising a third circuit (3) for generating at least one of said control signals (UP,DOWN).

2. Linear phase detector according to claim 1, wherein said third circuit (3) comprises a latch (30) receiving said first (CLK-Q) and second (CLK-I) clock signal and generating said first control signal (UP), with one of the latches (20) of the second circuit (2) generating the second control signal (DOWN).

3. Linear phase detector according to claim 2, wherein said reference signal (REF) is supplied to at least one control input of said multiplexers (12,22) and to clock inputs of said latches (10,11,20,21) of said first (1) and second (2) circuits, with said first clock signal (CLK-Q) being supplied to at least one data input of said latches (10,11) of said first circuit (1) and with said second clock signal (CLK-I) being supplied to at least one data input of said latches (20,21) of said second circuit (2).

4. Linear phase detector according to claim 1, wherein said third circuit (3) comprises first logical circuitry (31,32) receiving the latch output signals of said first circuit (1) for generating said first control signal (UP) and comprises second logical circuitry (33,34) receiving the latch output signals of said second circuit (2) for generating said second control signal (DOWN).

5. Linear phase detector according to claim 4, wherein said first logical circuitry (31,32) comprises at least a first (31) and second (32) EXOR gate, the first EXOR gate receiving said latch output signals from said first circuit (1), the second EXOR gate (32) receiving output signals from said first EXOR gate (31) and from a third EXOR gate (33) for generating said first control signal (UP), with said second logical circuitry (33,34) comprises at least said third (33) and a fourth (34) EXOR gate, the third EXOR gate (33) receiving said latch output signals from said second circuit (2), the fourth EXOR gate (34) receiving output signals from said third EXOR gate (33) and from a source for generating said second control signal (DOWN).

6. Linear phase detector according to claim 5, wherein said first logical circuitry (31,32,35) comprises a fifth EXOR gate (35) receiving said output signals from said first EXOR gate (31) and from a source for balancing said third circuit (3).

7. Linear phase detector according to claim 6, wherein said reference signal is supplied to at least one control input of said multiplexers (12,22) and to clock inputs of said latches (10,11,20,21), with said first clock signal being supplied to at least one data input of said latches (10,11) of said first circuit (1) and with said second clock signal being supplied to at least one data input of said latches (20,21) of said second circuit (2).

8. Apparatus comprising a linear phase detector for in response to at least one reference signal (REF) and at least a first (CLK-Q) and second (CLK-I) clock signal generating at least a first (UP) and second (DOWN) control signal and comprising at least a first circuit (1) receiving said reference signal (REF) and said first clock signal (CLK-Q) and a second circuit (2) receiving said reference signal (REF) and said second clock signal (CLK-I), wherein said first and second circuits (1,2) each comprise at least two latches (10,11,20,21) and at least one multiplexer (12,22) for multiplexing latch output signals, with said linear phase detector comprising a third circuit (3) for generating at least one of said control signals (UP,DOWN).

9. Method for linearly phase detecting through in response to at least one reference signal (REF) and at least a first (CLK-Q) and second (CLK-I) clock signal generating at least a first (UP) and second (DOWN) control signal and comprising a first step of receiving said fist clock signal (CLK-Q) and a second step of receiving said second clock signal (CLK-I) and a third step of receiving said reference signal (REF), wherein said method comprises a fourth step of latching said reference signal (REF) and one of said clock signals (CLK-Q) and of multiplexing latched signals and a fifth step of latching said reference signal (REF) and the other one of said clock signals (CLK-I) and of multiplexing latched signals and a sixth step of generating at least one of said control signals (UP,DOWN).

10. Processor program product for linearly phase detecting through in response to at least one reference signal (REF) and at least a first (CLK-Q) and second (CLK-I) clock signal generating at least a first (UP) and second (DOWN) control signal and comprising a first function of receiving said first clock signal (CLK-Q) and a second function of receiving said second clock signal (CLK-I) and a third function of receiving said reference signal (REF), wherein said processor program product comprises a fourth function of latching said reference signal (REF) and one of said clock signals (CLK-Q) and of multiplexing latched signals and a fifth function of latching said reference signal (REF) and the other one of said clock signals (CLK-I) and of multiplexing latched signals and a sixth function of generating at least one of said control signals (UP,DOWN).
